(19) United States
(12) Patent Application Publication
(10) Pub. No.: US 2010/0164101 A1
(43) Pub. Date: Jul. 1, 2010

(54) Ball land structure having barrier pattern

(75) Inventors: Wang-Jae Lee, Asan-si (KR); Yong-Jin Jung, Cheonan-si (KR); Jung-Hyeon Kim, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/654,477

(22) Filed: Dec. 22, 2009

(30) Foreign Application Priority Data
Dec. 31, 2008 (KR) 10-2008-0137857

(51) Int. Cl. H01L 23/498; H01R 12/04

(52) U.S. Cl. 257/738; 174/261; 257/E23.069

(57) ABSTRACT

Disclosed is a ball land structure suitable for use with a semiconductor package. The ball land structure includes a ball land and a barrier on a core. The barrier may be configured to connect to the ball land so as to form a barrier hole between an edge of the ball land and an edge of the barrier thus exposing a portion of the core. A solder mask may be deposited on the ball land and a portion of the core exposed by the barrier hole so as to partially expose the core.

### PRIORITY STATEMENT

This application claims priority under 35 U.S.C. §119 to Korean Patent Application No. 10-2008-0137857, filed on Dec. 31, 2008, in the Korean Intellectual Property Office (KIPO), the entire contents of which are herein incorporated by reference.

### BACKGROUND

1. Field

Example embodiments relate to a ball land structure having a barrier surrounding an exposed region of a core which may prevent or retard propagation of a core crack to a neighboring pattern crack.

2. Description of Related Art

In response to a trend aiming at compact and lightweight integrated circuit devices having relatively high reliability, there are increasing demands for smaller package devices having more input/output pins. A quad flat package (QFP) and a ball grid array (BGA) package are capable of providing many input/output pins, which correspond to this recent trend.

In QFP technology, the leads may be spaced to have a relatively small pitch. Thus, BGA package technology which can reduce an overall size of a device and freely arrange a contact portion, has attracted attention for its effectiveness when many contact portions are needed. Moreover, compared to a plastic package using a lead frame, the BGA package can be reduced in size by 30% or more, and can be as small as a chip (die) when a ball pitch is 1.00 mm or less, resulting in embodying a chip-scale package or a chip-size package. However, in QFP technology, a lead may be easily damaged by impact due to the relatively small pitch.

For the BGA package, reliability is one of the important problems to solve, and particularly, an increase in reliability of a solder ball joint portion is important. When the solder ball joint portion is disconnected, electrical disconnection occurs, resulting in fatal defects in the device. Particularly, when a crack is generated due to damage at a joint portion, an electrical resistance in the joint portion increases, so that electrical characteristics of the package device cannot be ensured. When the electrical resistance in the solder joint portion increases, DC voltage drop occurs in a signal transmission path, charge delay of an RC circuit may be induced, and noise is generated on a system level.

### SUMMARY

Example embodiments provide a ball land structure in which a solder ball joint portion is not voluntary disconnected, thus reinforcing solder ball joint reliability.

Example embodiments also provide a ball land structure which may enhance stress characteristics that may be degraded in a core portion adjacent to a ball land when the core is partially exposed, thus enhancing solder ball joint reliability.

Example embodiments also provide a ball land structure having an NSMD (non-soldermask defined) ball land structure suggested to enhance solder ball joint reliability, which may prevent or retard a pattern crack in which an input/output pattern adjacent to a ball land may be disconnected by also enhancing stress characteristics.

In accordance with example embodiments, a ball land structure may include a ball land on a core and a barrier on the core. The barrier may be configured to connect to the ball land so as to form a barrier hole between an edge of the ball land and an edge of the barrier to expose a portion of the core. A solder mask may be formed on the ball land and a portion of the core exposed by the barrier hole so as to partially expose the core.

Example embodiments provide for a ball land structure, including a ball land formed on a core, and fused with solder balls. An input/output pattern may be integrally formed with the ball land and configured to connect a semiconductor chip with the ball land. A solder mask including a cover region may be applied on the core to protect the ball land and/or the input/output pattern and an open region not applied on the core such that the ball land is connected with the solder balls. The open region may include a joint region exposing the ball land and an exposure region exposing a part of a surface of the core. The ball land structure may further include a barrier configured to prevent or retard a propagation of a crack generated in the core of the exposure region to the solder mask adjacent to the exposure region and to the neighboring input/output pattern.

In accordance with example embodiments, the barrier may extend in an opposite direction of the joint region from both sides of the ball land, and may be formed in a ring type around the exposure region, such that a buffer hole corresponding to the exposed region may be formed between the ball land and the barrier.

In accordance with example embodiments, the joint region may be smaller than the ball land in size, and the exposure region may be smaller than or equal to the buffer hole in size. In example embodiments, the core may be formed of a reel-type polyimide tape.

In accordance with example embodiments, the solder mask may be formed in a combination type of an SMD (solder mask defined) structure partially exposing a middle portion of the ball land excluding an edge thereof through the open region, and an NSMD structure completely exposing the ball land.

In accordance with example embodiments, the crack generated in the exposure region of the core may be generated due to a difference in thermal expansion or thermal contraction between the core and the solder mask. Whether or not the thermal expansion or thermal contraction occurs when stress is concentrated at the exposure region of the core between the ball land and the solder mask may be determined after a temperature cycle test performed at −55 to 125° C. during 1000 cycles.

Example embodiments also provide for a ball land structure including a ball land pattern fused with solder balls, an input/output pattern connected with the ball land pattern, and a barrier configured to surround at least a part of a core whose surface adjacent to the ball land is partially exposed to enhance joint reliability of the solder balls with respect to the ball land, thereby preventing or retarding propagation of a crack that may cause disconnection of the input/output pattern when stress is concentrated at the exposed surface of the core.

In accordance with example embodiments, the solder ball joint reliability (SJR) may increase as the exposed region of the core becomes larger, the stress may increase as the exposed region of the core becomes larger, and the barrier pattern may be a ring-type pattern preventing or retarding propagation of the crack in the core to a crack in the input/output pattern.

### BRIEF DESCRIPTION OF THE DRAWINGS

Example embodiments are described in further detail below with reference to the accompanying drawings. It should be understood that various aspects of the drawings may have been exaggerated for clarity.

FIG. 1 is a plan view showing a configuration of a semiconductor package to which solder balls are attached without a solder mask;

FIG. 2 is a plan view showing a configuration of a semiconductor package having neither a solder mask nor solder balls;

FIG. 3 is a schematic cross-sectional view taken along line of FIG. 2;

FIG. 4 is a plan view showing a configuration of a reel tape having a core formed in a reel type;

FIG. 5 is a plan view of enlarged portion a of FIG. 2, showing a solder mask defined (SMD) ball land structure;

FIG. 6 is a cross-sectional view taken along line VI-VI of FIG. 5;

FIG. 7 is a plan view of enlarged portion b of FIG. 2, showing a non-solder mask defined (NSMD) ball land structure;

FIG. 8 is a cross-sectional view taken along line VIII-VIII of FIG. 7;

FIG. 9 is a plan view of enlarged portion c of FIG. 2, showing a ball land structure formed in a combination type of SMD and NSMD structures;

FIG. 10 is a cross-sectional view taken along line X-X of FIG. 9;

FIG. 11 is a plan view showing a configuration in which a core crack propagates to an input/output pattern;

FIG. 12 is a plan view of a combination-type ball land structure including a barrier when a solder mask is applied; and

FIG. 13 is a plan view of a combination-type ball land structure including a barrier when a solder mask is removed.

### DETAILED DESCRIPTION

Example embodiments will now be described more fully with reference to the accompanying drawings in which example embodiments are shown. In the drawings, the thicknesses of layers and regions may be exaggerated for clarity.

Example embodiments are disclosed herein. However, specific structural and functional details disclosed herein are merely representative for purposes of describing example embodiments. This invention, however, may be embodied in many alternate forms and should not be construed as limited to only example embodiments set forth herein.

Accordingly, while example embodiments are capable of various modifications and alternative forms, example embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements that may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments of a ball land structure in which both solder ball joint reliability and stress characteristics are improved by exposing a part of a core adjacent to a ball land and forming a barrier surrounding the exposed region will be described with reference to the accompanying drawings in detail.

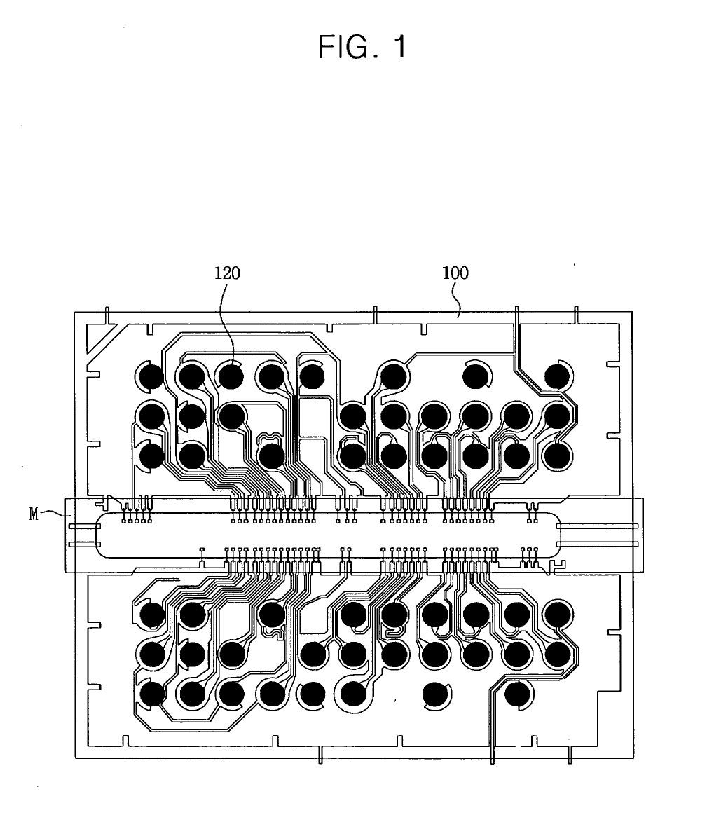

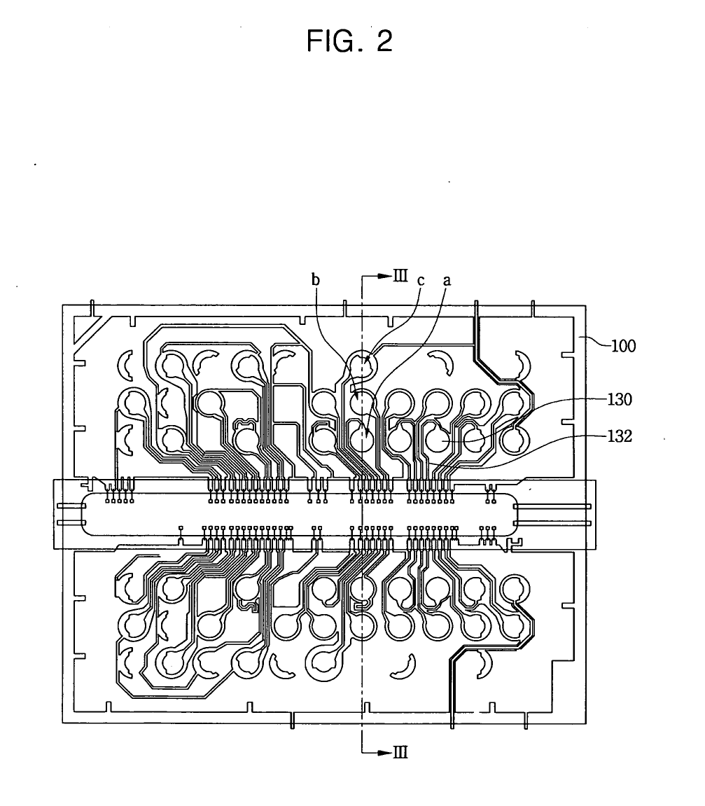

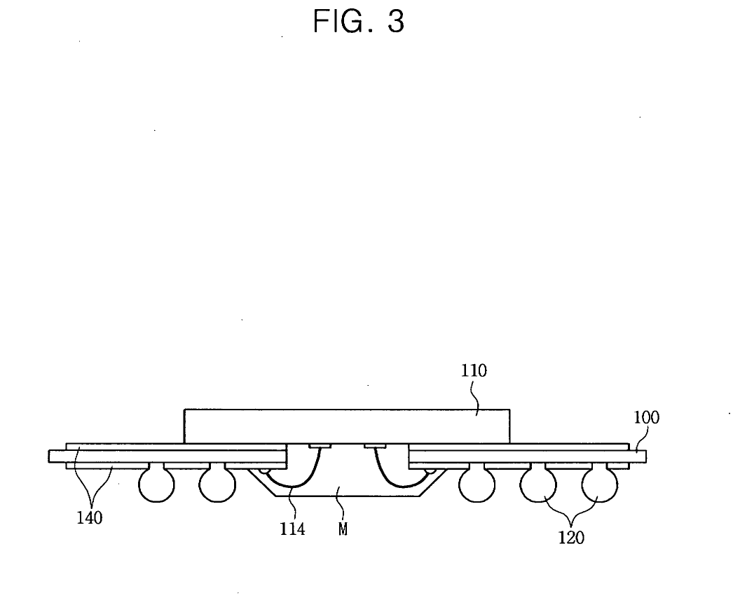

FIG. 1 is a plan view showing a configuration of a semiconductor package to which solder balls are attached without a solder mask, FIG. 2 is a plan view showing a configuration of a semiconductor package having neither a solder mask nor solder balls, and FIG. 3 is a schematic cross-sectional view taken along line of FIG. 2. However, in FIG. 1, a solder mask is omitted.

Referring to FIGS. 1 to 3, a semiconductor chip 110 may be attached on a top surface of a double-sided core 100. The core 100 may be a printed circuit board (PCB) or a substrate having an interconnection disposed on its surface like a lead frame or polyimide tape. The core 100 may be a panel-type core or a reel-type thin film core.

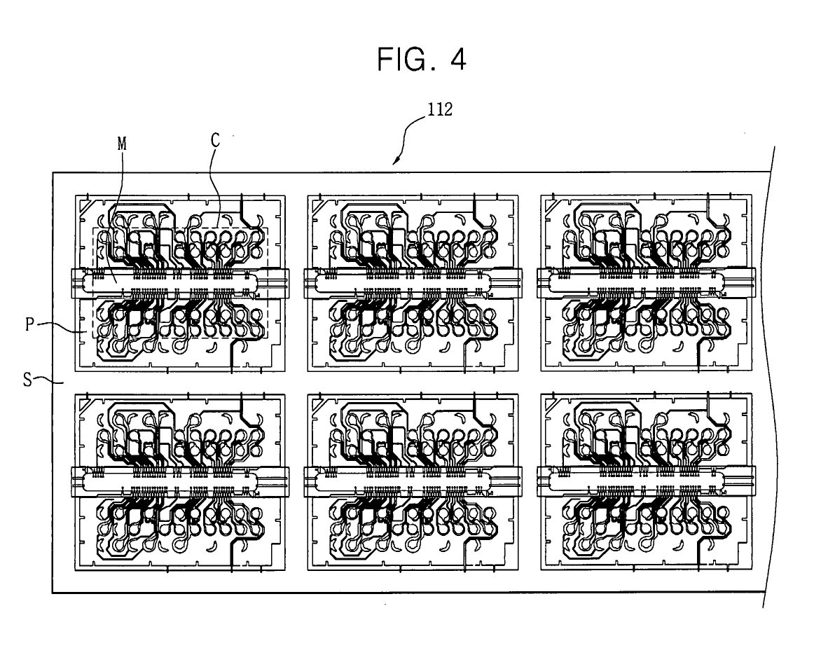

In example embodiments, the core 100 may be composed of a reel tape 112 (see FIG. 4). The reel tape 112 may include a copper interconnection and a solder mask which may be mounted on the core 100. The core 100 may be formed of a polyimide tape, and a plurality of cores 100 may be connected with each other in a line. Thus, FIG. 4 is a plan view showing a configuration of the reel tape 112 in which cores 100 are formed in a reel type.

Referring to FIGS. 3 and 4, the reel-type core 100 may be divided into a package region P and a scribe region S. The package region P may include a mounting region C in which a semiconductor chip 110 may be mounted, and a molding region M that may be filled with an epoxy molding compound (EMC). In the molding region M, a bonding pad (not shown) included in the semiconductor chip 110 and a bonding pad (not shown) included in the core 100 may be electrically connected with each other by a wire 114. A molding member (filling the molding region M) for protecting a chip may also be formed over the semiconductor chip 110.

As shown in FIG. 1, a plurality of solder balls 120 may be formed on a bottom surface of the core 100. The solder balls 120 may be disposed in a regular pattern, for example, a lattice shape, and may be disposed at regular intervals on the entire surface of the core 100. The example package illustrated in FIG. 1 has a fan-out structure in which the solder balls 120 may also be attached to regions other than the mounting region C (of FIG. 4) in which the semiconductor chip 110 may be mounted.

A region in which solder ball 120 may be formed on the bottom surface of the core 100 is referred to as a ball land 130. Broadly, the ball land structure may be classified into two types: one is a solder mask defined (SMD) structure; and the other is a non-solder mask defined (NSMD) structure.

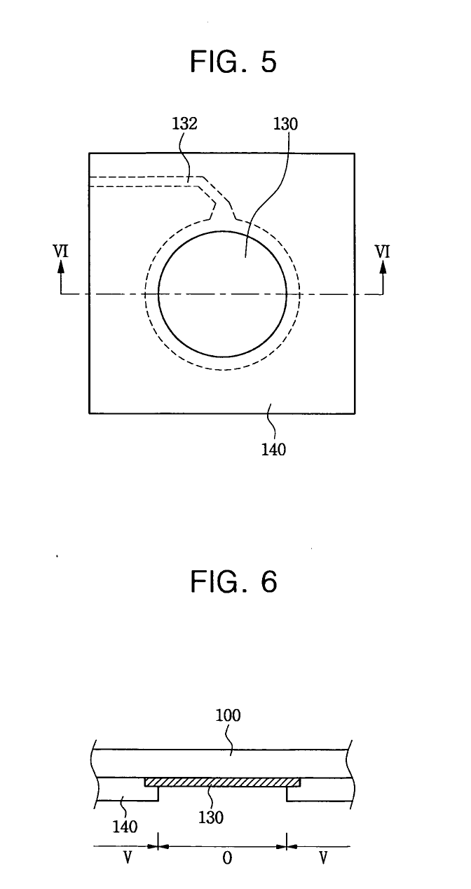

FIG. 5 is a plan view of enlarged portion a of FIG. 2, showing the SMD ball land structure, and FIG. 6 is a cross-sectional view taken along line VI-VI of FIG. 5.

Referring to FIGS. 5 and 6, it can be seen that an input/output pattern 132 may be formed in a line shape. It can also be seen that the input/output pattern 132 may be connected with the ball land 130. As shown in FIGS. 5 and 6, the input/output pattern 132 and the ball land 130 may be integrated on the bottom surface of a core 100. In accordance with example embodiments, a solder mask 140 may be applied to a surface of the core 100 excluding the ball land 130 to protect the core 100 and the input/output pattern 132. The solder mask 140 may also partially protect the ball land 130. As shown in FIG. 6, the solder mask 140 may form a cover region V. An open region O, a region to which the solder mask 140 is not applied, may be formed so that the ball land 130 may be fused with a solder ball 120. Most regions of the ball land 130, excluding an edge of the ball land 130, are exposed to the outside through the open region O of the solder mask 140. Thus, in the SMD ball land structure, the solder mask 140 may be applied up to, and/or partially over, the edge of the ball land 130.

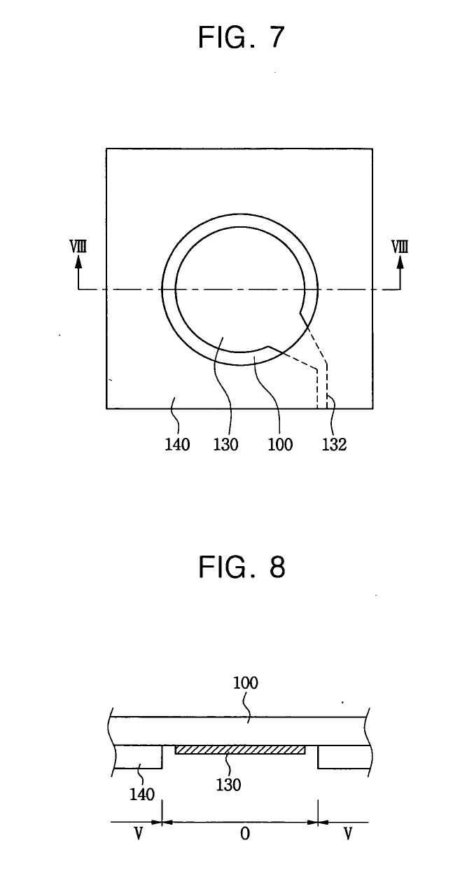

FIG. 7 is a plan view of enlarged portion b of FIG. 2, showing the NSMD ball land structure, and FIG. 8 is a cross-sectional view taken along line VIII-VIII of FIG. 7.

Referring to FIGS. 7 and 8, it is noted that a ball land 130 and an input/output pattern 132 connected with the ball land 130 may be formed on the bottom surface of a core 100 as described above. In accordance with example embodiments, a solder mask 140 may be applied to a portion excluding the entire ball land 130 and a part of the input/output pattern 132 adjacent to the ball land 130. As in FIGS. 5-6, the solder mask 140 illustrated in FIGS. 7-8 may form a cover region V. However, the solder mask 140 formed on the core 100 illustrated in FIGS. 7-8 is not formed on the part of the input/output pattern 132 connected with the ball land 130, the entire ball land 130, and a part of the surface of the core 100 adjacent to the ball land 130. Accordingly, the portion of the input/output pattern 132 connected to the ball land 130, the entire ball land 130, and a part of the surface of the core 100 adjacent to the ball land 130 form an open region O of the solder mask 140. Thus, in the NSMD ball land structure, none of the ball land 130 is covered with the solder mask 140.

The aforementioned SMD ball land structure and NSMD ball land structure provide the following advantages and disadvantages, respectively.

In the SMD ball land structure, the edge of the ball land 130 may be covered with the solder mask 140, so that this structure may be relatively strong against stress applied from outside. However, in the SMD ball land structure, a ball neck shape may be formed when the solder balls 120 are formed in the ball land 130, so that solder ball joint reliability may be degraded, which may be a fatal disadvantage.

Compared to the SMD ball land structure, in the NSMD ball land structure, the ball land 130 may be completely exposed, so that a ball neck shape is not formed, and this structure may be relatively strong against stress applied from inside. However, the NSMD ball land structure may have a pattern crack extending through the input/output pattern 132. Furthermore, because the ball land may be completely exposed, a joint strength between the ball land and the core may become weak, and this structure may be vulnerable to delamination.

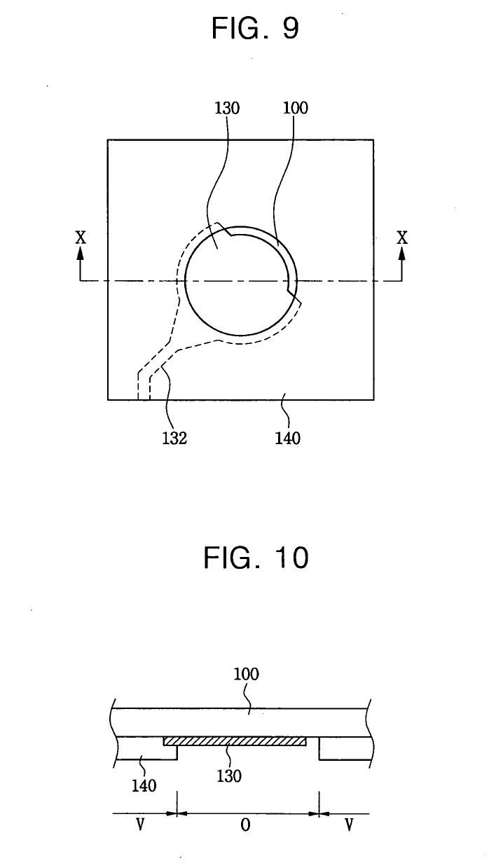

FIG. 9 is a plan view of enlarged portion c of FIG. 2, showing the combination-type ball land structure according to example embodiments, and FIG. 10 is a cross-sectional view taken along line X-X of FIG. 9.

A ball land 130 and an input/output pattern 132 may be integrally formed and disposed above or on a core 100, and a solder mask 140 may be applied over a part of the ball land 130 and the input/output pattern 132 to protect the core 100 and the input/output pattern 132, which forms a cover region V as described above.

In example embodiments, the combination-type ball land structure is a combination of the SMD ball land structure and the NSMD ball land structure. As explained earlier, an SMD open region O to which the solder mask 140 is not applied is included as a part of a middle portion of the ball land 130, so that the middle portion of the ball land 130 is exposed. An NSMD open region O includes the entire ball land 130, a part of the input/output pattern 132 and a part of the surface of the core 100 adjacent to the ball land 130, so that the entire middle portion of the ball land 130, the input/output pattern 132 adjacent thereto, and the part of the surface of the core 100 are exposed.

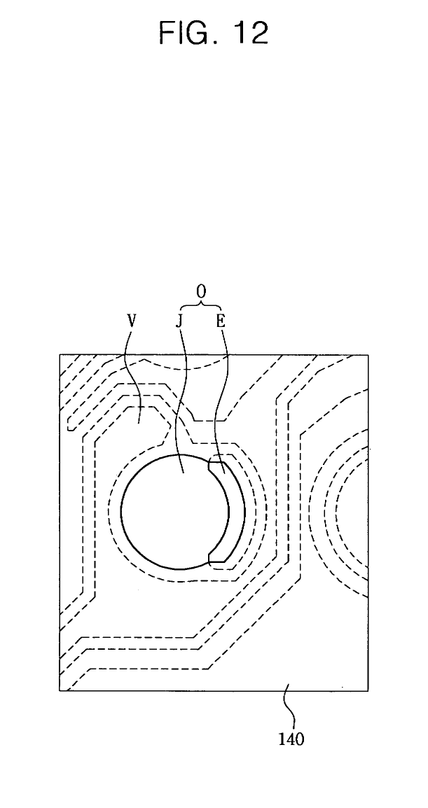

The open region O of the combination-type ball land structure partially covered by the solder mask 140 may be divided into a joint region J exposing the ball land 130 and an exposure region E exposing the core 100 as shown in FIG. 12.

In example embodiments, during an annealing process, stress may be concentrated at the exposure region E which may result in a generation of a crack in the input/output pattern 132. Particularly, in the exposure region E of the NSMD ball land structure of FIG. 8 or the combination-type ball land structure having the SMD and NSMD structures of FIG. 10, a difference in thermal expansion or thermal contraction between the core 100 and the solder mask 140 may be relatively large, so that the stress may be more concentrated.

The difference in thermal expansion coefficients (CTE) between the core 100 and the solder mask 140 may be a primary contributor to the generation of a pattern crack that may be present in the NSMD ball land structure or the combination-type ball land structure. A reel-to-reel type core may be relatively vulnerable to thermal expansion or thermal contraction as compared to a panel-type core. Particularly, a BOC-type package (board-on-chip) structure in which a semiconductor chip is directly mounted on a PCB without a lead frame may have a semiconductor chip and a PCB with significant differences in thermal expansion or thermal contraction. Thus, in the reel-to-reel type package structure, stress may be more concentrated at the exposure region than in package structures in which cores are individually packaged like sheet-type or panel-type cores. This is because the sheet-type or panel-type core is cut in a strip shape and packaged, so that it is made by weaving 3 plies of weft and warp-thread fabrics between polyimide resin layers to reinforce endurance. However, the reel-to-reel type core is rolled on a reel and simultaneously packaged, so that it is made by weaving one ply of fabric in-between the polyimide resin layers. Thus, when temperature cycling (TC) is performed at −55 to 125° C., the stress may be concentrated at the exposed core 100 in TC 1000 cycles, and thus the pattern crack may be generated.

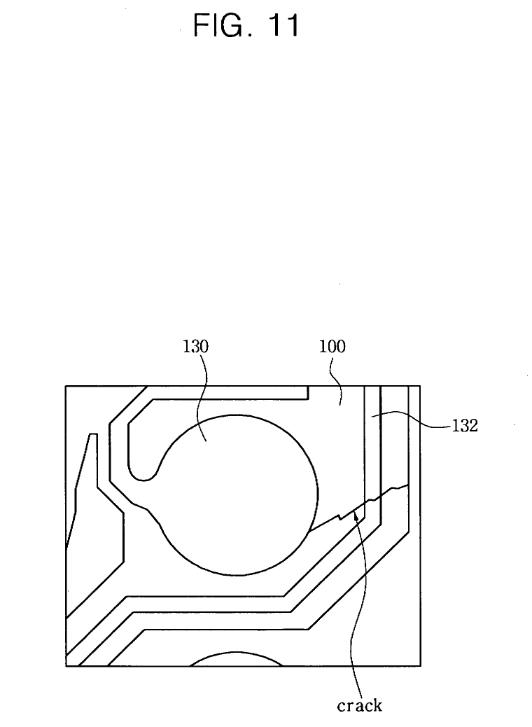

Likewise, as shown in FIG. 11, due to the difference in CTE between the solder mask 140 and the core 100, a crack may be first generated in the core 100 located in the exposure region E. Although not shown in FIG. 11, the crack may be seeded, and thus propagates to the adjacent solder mask 140. As shown in FIG. 11, the crack in the solder mask 140 may propagate again to the adjacent input/output pattern 132, resulting in generation of another crack in the input/output pattern 132. The crack in the input/output pattern 132 may become a cause of electrical failures.

Particularly, the generation of cracks due to thermal expansion or thermal contraction may be more frequent in a fully buffered dual in-line memory module (FBDIMM) in which memories are mounted on both surfaces of a PCB for high speed operating performance of a memory.

In example embodiments, an SMD ball land structure or combination-type ball land structure may have a need to prevent or reduce degradation in solder ball joint reliability occurring in the ball neck shape, and to minimize or reduce the concentration of the stress caused by the difference in thermal expansion or thermal contraction between the solder mask and the core in the open region. For example, the ball land structure should be improved not to allow a crack to propagate to a line-shape input/output pattern even when the crack is generated in TC 1000 cycles.

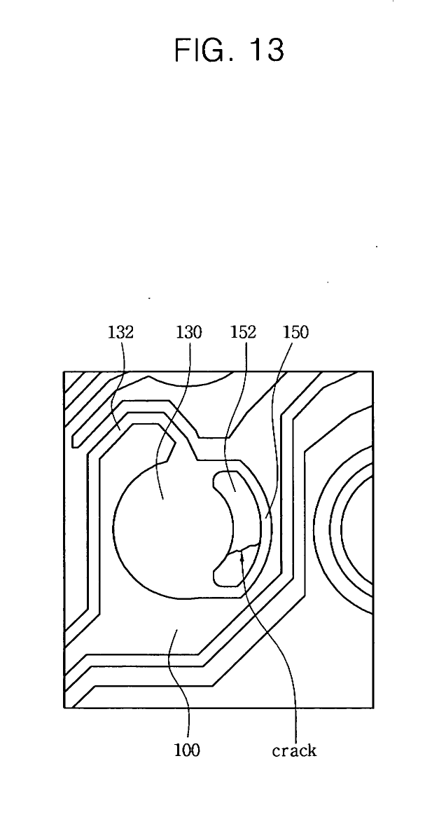

FIG. 12 is a plan view of a combination-type ball land structure including a barrier when a solder mask is applied, and FIG. 13 is a plan view of a combination-type ball land structure including a barrier when a solder mask is removed.

Referring to FIG. 13, a ball land 130 and an input/output pattern 132 may be integrally formed over a core 100, and a solder mask (not shown) may be applied over a part of the ball land 130 and the input/output pattern 132 to protect as described above. The ball land 130 may be formed in a shape corresponding to solder balls 120 over the core 100, and connected with the input/output pattern 132. Because a solder mask may be formed to protect the ball land 130 and the input/output pattern 132, a cover region V may be present on the a substantial portion of the surface of the core 100 or the entire surface of the core 100. In addition, the solder mask necessarily includes an open region O such that the ball land 130 may be joined with the solder balls 120.

The combination-type structure may include a region partially exposing a middle portion of the ball land 130, excluding an edge thereof, through the open region O in the SMD part, and a region completely exposing the ball land 130 through the open region O in the NSMD part. The former region is referred to as a joint region J because it may be directly joined with the solder balls 120, and the latter region is referred to as an exposure region E because a surface of the core 100 may be exposed. The combination-type structure may further include a barrier 150 to prevent propagation of a crack, which may be generated in the core 100 in the exposure region E, to a solder mask 140 adjacent to the exposure region E, and then to the neighboring input/output pattern 132.

The barrier 150 may extend in an opposite direction of the joint region J from both sides of the ball land 130, and may be formed in a ring type around the exposure region E. A buffer hole 152 may be formed between the ball land 130 and the barrier 150 to expose a portion of the core 100.

In the SMD part, the middle portion of the ball land 130, excluding the edge thereof, may be partially exposed by the open region O, and the ball land 130 may be joined with the solder balls 120 through the open region O. Thus, the joint region J joined with the solder balls is smaller than the ball land 130 in size.

In the NSMD part, the ball land 130 may be completely exposed by the open region O, and a part of the surface of the core 100 may be exposed through the open region O. Thus, the exposure region E exposing the core 100 may be smaller than or equal to the buffer hole 152 in size.

As described above, in the SMD ball land structure, solder ball joint reliability between solder balls and a ball land may be degraded, so that the solder balls may be randomly separated or dislocated, and in the NSMD ball land structure, solder ball joint reliability may be enhanced, however a crack may be generated in an open region. Accordingly, in a package structure including the NSMD ball land structure, a part of a core adjacent to a ball land may be exposed, so that stress is concentrated at the exposed core, and thus a crack may be generated. Such a core crack may propagate to a crack in a solder mask, and further into a crack in an input/output pattern. For this reason, example embodiments further includes a barrier which may be integrated with the ball land to surround the exposed region of the core so as to prevent propagation of the crack in the core to crack in the input/output pattern.

As described above, example embodiments may provide the following effects:

First, when an open region is formed to expose at least a part of a core adjacent to a ball land, joint reliability between the ball land and solder balls may be enhanced.

Second, when the open region is formed in a solder mask to expose a part of the core adjacent to the ball land, the solder ball joint reliability may be directly proportional to the size of the open region, but stress characteristics at the exposed core portion are inversely proportional to the size of the open region. Thus, when a barrier is further included in the exposed core portion, both the solder ball joint reliability and the stress resistance characteristics may be enhanced.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A ball land structure, comprising:
a ball land on a core;
a barrier on the core, the barrier being configured to connect to the ball land so as to form a barrier hole between an edge of the ball land and an edge of the barrier to expose a portion of the core; and
a solder mask on the ball land and the portion of the core exposed by the barrier hole to partially expose the core.

2. The ball land structure according to claim 1, further comprising:
an input/output pattern on the core, wherein the input/output pattern is connected to the ball land and the solder mask covers the input/output pattern.

3. The ball land structure according to claim 1, wherein the solder mask includes
a cover region covering the core and at least part of the ball land, and
an open region exposing at least a portion of the ball land.

4. The ball land structure according to claim 3, wherein the open region includes a joint region exposing the ball land and an exposure region exposing the core in the barrier hole.

5. The ball land structure according to claim 4, wherein the barrier encloses the exposure region.

6. The ball land structure according to claim 5, wherein the barrier is a ring type around the exposure region.

7. The ball land structure according to claim 6, wherein the joint region is smaller than the ball land in size, and the exposure region is smaller than or equal to the barrier hole in size.

8. The ball land structure according to claim 1, wherein the core is formed of a reel-type polyimide tape.

9. The ball land structure according to claim 1, wherein the solder mask covers a portion of an edge of the ball land and does not cover another portion of an edge of the ball land.

10. The ball land structure according to claim 1, wherein the core includes a crack in a portion of the core corresponding to the barrier hole.

11. The ball land structure according to claim 1, further comprising:
a solder ball fused to the ball land.

12. The ball land structure according to claim 11, wherein the solder ball includes a first portion contacting a portion of the solder mask and a second portion that does not contact the solder mask.

13. The ball land structure according to claim 12, wherein the solder ball includes a necked portion at the interface between the solder mask and the solder ball.

14. The ball land structure according to claim 11, wherein the solder mask includes a cover region covering the core and at least part of the ball land, an open region exposing at least a portion of the ball land, the open region includes a joint region, and the solder ball is connected to the joint region.

15. A semiconductor package comprising:
the ball land structure according to claim 1.
